(19) United States
(12) Patent Application Publication
(10) Pub. No.: US 2026/0303035 A1
(43) Pub. Date: Oct. 1, 2026

(54) Circuit and Method for Operating a Circuit

(71) Applicant: Delft Semiconductor B.V., Bergschenhoek (NL)

(72) Inventor: Rudolphe Gustave Hubertus Eschauzier, Bergschenhoek (NL)

(21) Appl. No.: 19/478,037

(22) PCT Filed: Apr. 24, 2024
(86) PCT No.: PCT/NL2024/050214

§ 371 Date: Oct. 23, 2025

(30) Foreign Application Priority Data
Apr. 26, 2023 (NL) 2034706

(51) Int. Cl. H03F 1/32; H03F 3/387

(52) U.S. Cl. CPC H03F 1/32; H03F 3/387; H03F 2200/375

(57) ABSTRACT

The present disclosure relates to a circuit and to a method for operating a circuit. The circuit has a circuit input and a circuit output, and comprises an auto-zeroing amplifier with an amplifier and auto-zeroing circuitry. The auto-zeroing amplifier is operable in an auto-zeroing phase in which the auto-zeroing circuitry is configured to sample an offset signal of the amplifier, the offset signal being indicative of an offset of the amplifier, and an output phase in which the auto-zeroing amplifier is configured to provide an auto-zeroed output signal corresponding to an output signal of the amplifier combined with said sampled offset signal. The circuit further comprises an input chopper electrically connected between the circuit input and an input of the auto-zeroing amplifier, an output chopper electrically connected between the output of the auto-zeroing amplifier and the circuit output, and a control unit configured to control the auto-zeroing amplifier, the input chopper and the output chopper such that, in a time period from the auto-zeroing amplifier entering output phase operation to again entering the output phase operation following the auto-zero phase operation, the sampled offset signal in the auto-zeroed output signal is substantially averaged out at the circuit output.

### FIELD

The present disclosure generally relates to a circuit. The present disclosure also relates to a method for operating a circuit. The present disclosure especially relates to suppressing offset and noise in circuits, such as amplifier circuits.

### BACKGROUND

In most signal processing applications, circuits ideally linearly process an input signal. However, practical circuits suffer from non-idealities that limit the accuracy of this signal processing. These non-idealities appear as error sources in the output signal of the circuit. Key performance specifications relating to such non-idealities typically include offset and noise.

An offset in a circuit causes a fixed difference between the ideal output signal of the circuit and the actual output signal. In other words, in absence of an input signal to the circuit, the offset of the circuit nevertheless causes a non-zero output signal that can be observed at the output of the circuit. Noise, on the other hand, introduces a varying output signal caused by stochastic variation within the circuit, for example due to thermal noise. Since the offset and noise are both generally independent of the input signal, the relative error due to offset and noise increases as the input signal decreases.

Offset may be present in the form of a voltage or a current in various types of analog, digital and mixed-signal circuits. Typically, offset is represented in an input-referred form. In various practical circuits, offset may be caused by statistical mismatch between components of the circuit.

Various offset compensation techniques are known in the art, and can generally be divided in static offset compensation and dynamic offset compensation. Static offset compensation refers to calibrating the circuit before use, and fixing the degree of compensation based on the calibration. However, since offset can change over time (e.g., due to temperature drift), a mismatch between the offset compensation and the actual offset may appear after some time. In that case, an effective offset corresponding to the difference between the original offset and the offset compensation can be observed. Dynamic offset compensation aims to address this issue by continuously or periodically adjusting the offset compensation. Examples of dynamic offset compensation known in the art for example include chopper stabilization and auto-zeroing.

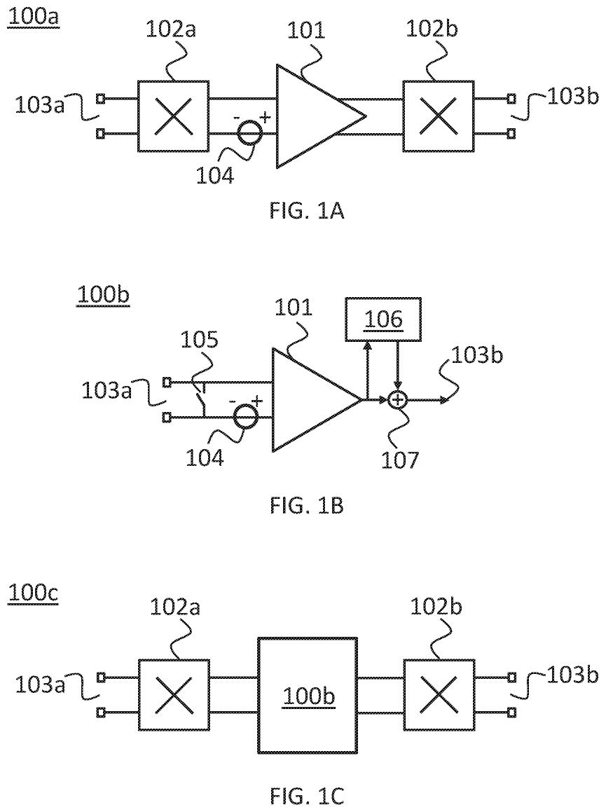

In FIG. 1A, an exemplary chopper stabilized circuit 100a is shown including an amplifier 101, an input chopper 102a and an output chopper 102b. An input signal can be applied at a circuit input 103a. The signal is amplified by amplifier 101 and output by circuit 100 at a circuit output 103b. Amplifier 101 may have an offset 104, in this example represented as an input-referred offset voltage source. Although FIG. 1A relates to amplifier circuits having an offset, a similar circuit may be obtained using other offset-exhibiting circuits.

Chopper stabilization relies on input chopper 102a and output chopper 102b periodically swapping the polarity of a signal applied to it, referred to as ‘chopping’. In particular, input chopper 102a and output chopper 102b may be configured to effectively multiply its input signal by +1 or −1 and output the result. In other words, they may be operable in a first mode, corresponding to multiplication by +1, and a second mode, corresponding to multiplication by −1. Although not shown in FIG. 1A, a control unit may be used to control the operating mode of input chopper 102a and output chopper 102b using a chopper control signal.

In differential circuits, such as circuit 100a shown in FIG. 1A, this may be achieved by simply swapping the signal paths for the input terminals depending on the desired polarity. For example, input chopper 102a and output chopper 102b periodically couple or cross-couple its input and output. However, choppers as described above are also applicable to single-ended circuits or a circuit including a combination of single-ended and differential elements.

Since any input signal presented at circuit input 103a is chopped twice, the polarity of the input signal appears unchanged at circuit output 103b irrespective of the operating mode of the input chopper 102a and output chopper 102b. However, offset 104 is only chopped by output chopper 102b, resulting in an offset signal being presented at circuit output 103b with an alternating polarity in accordance with the operating mode of output chopper 103b. Typically, input chopper 102a and output chopper 102b are controlled using a periodic signal having a chopper frequency fchop with a duty cycle of about 50%. On average, over a cycle of operating in the first and second mode, the offset contribution to the output signal at circuit output 103b can be at least partially compensated.

A drawback of the abovementioned method, however, is that this alternating offset signal will appear as an output ripple at circuit output 103b. Filtering can limit this ripple, but will also limit the available bandwidth of the output signal.

In FIG. 1B, an exemplary auto-zeroing circuit 100b is shown, comprising amplifier 101 with offset 104, a nulling switch 105, a sample-and-hold unit 106, and a combining unit 107. It will be appreciated by the skilled person that auto-zeroing circuit 100b as shown in FIG. 1B is merely exemplary and that other forms of auto-zeroing circuitry can be used instead.

Auto-zeroing circuit 100b can be periodically operated in an auto-zero phase in which nulling switch 105 is actuated to be in a closed state (i.e., conducting) and in which sample-and-hold unit 106 is configured to sample a signal at the output of amplifier 101. Since the input of amplifier 101 is shorted (i.e., short-circuited) by nulling switch 105, the sampled signal corresponds to an offset signal of the amplifier. In particular, sample-and-hold unit 106 samples a signal corresponding to (input-referred) offset 104 amplified by amplifier 101.

After operating in the auto-zero phase, the auto-zeroing circuit 100b can be controlled to operate in the output phase in which the nulling switch 105 is actuated to be in an open state (i.e., not conducting). Here, the sampled offset signal is combined with the output signal from amplifier 101 by a combining unit 107 (e.g., a summing circuit) such that the offset component in the output signal of amplifier 101 is removed. By alternatingly operating in the auto-zero phase and the output phase, the offset can be dynamically eliminated or mitigated.

A drawback of the auto-zeroing technique, however, is that the sample-and-hold action introduces wide-band noise sampling into the circuit. In particular, sampling the output signal of amplifier 101 in the auto-zero phase not only captures the offset of amplifier 101, but also an instantaneous noise value present at the output of amplifier 101. This instantaneous noise value is then propagated to circuit output 103b in the subsequent output phase. Due to the random variation of noise, the instantaneous noise value can vary significantly in each output phase, contributing to a reduced accuracy of the output signal at circuit output 103b. In the frequency domain, this translates to an increased noise floor, typically in the signal band.

The chopper stabilization and auto-zeroing can be combined in a single circuit, for example in a circuit 100c as shown in FIG. 1C. Circuit 100c comprises input chopper 102a, output chopper 102b, and auto-zeroing circuit 100b. For convenience, a more detailed view of auto-zeroing circuit 100b is omitted from FIG. 1C. Using chopper stabilization and auto-zeroing simultaneously may mitigate in part the drawbacks of the respective techniques. However, further improvements of output ripple and noise may be desired or even needed in some applications.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth below.

According to an aspect of the present disclosure, a circuit is provided having a circuit input and a circuit output. The circuit comprises an auto-zeroing amplifier comprising an amplifier and auto-zeroing circuitry, and being operable in an auto-zeroing phase in which the auto-zeroing circuitry is configured to sample an offset signal of the amplifier, the offset signal being indicative of an offset of the amplifier, and an output phase in which the auto-zeroing amplifier is configured to provide an auto-zeroed output signal corresponding to an output signal of the amplifier combined with said sampled offset signal. The circuit further comprises an input chopper electrically connected between the circuit input and an input of the auto-zeroing amplifier, and an output chopper electrically connected between the output of the auto-zeroing amplifier and the circuit output.

The circuit according to the present disclosure further comprises a control unit configured to control the auto-zeroing amplifier, the input chopper and the output chopper such that, in a time period from the auto-zeroing amplifier entering output phase operation to again entering the output phase operation following the auto-zero phase operation, the sampled offset signal in the auto-zeroed output signal is substantially averaged out at the circuit output.

The control unit according to the present disclosure ensures that the sampled offset signal is averaged out at the circuit output specifically over a period including output phase operation and a subsequent auto-zero phase operation. The Applicant has found that such operation of the input chopper and output chopper can further decrease the noise in the circuit. Here, it is noted that the offset signal in practice may inherently include noise as well, such that the sampled offset signal includes both a component reflecting a sampled offset and another component reflecting a sampled instantaneous noise value. In that sense, the (sampled) offset signal is nevertheless indicative of the offset of the amplifier.

The auto-zeroing amplifier of the circuit according to the present disclosure may drive a reactive (e.g., capacitive) load coupled externally to the circuit at the circuit output, or the circuit may include a subsequent amplifying stage with a reactive element. As an example only, the subsequent amplifying stage may include an integrator with a feedback capacitor. In those cases, when the auto-zeroing amplifier enters the auto-zeroing phase and/or when the signal path from the amplifier output to the circuit output is interrupted, for example by output chopper, noise sampled by the auto-zeroing circuitry during the previous auto-zeroing phase may still contribute to the output signal at the circuit output.

To mitigate this, the control unit takes into account the abovementioned time period when controlling the auto-zeroing amplifier, the input chopper and the output chopper in a manner that, at the circuit output, the sampled offset signal propagated from the auto-zeroing amplifier is averaged out over said time period. As a result, the circuit according to the present disclosure can exhibit both a reduced offset and a reduced noise regardless of the load presented at the circuit output.

The input chopper and the output chopper may each be configured to be operable in a first mode and a second mode. In the first mode, the input chopper and the output chopper may be configured to multiply an input signal thereof by +1 or to directly couple an input thereof to an output thereof. In the second mode, the input chopper and the output chopper may be configured to multiply an input signal thereof by −1 or to cross-couple the input thereof to the output thereof. The control unit may then be configured to control the input chopper and the output chopper such that, in said time period, the sum of each first time interval, during which the input chopper and output chopper operate in the first mode, and each second time interval, during which the input chopper and output chopper transition from the first mode to the second mode, is substantially equal to the sum of each third time interval, during which the input chopper and output chopper operate in the second mode, and each fourth time interval, during which the input chopper and output chopper transition from the second mode to the first mode.

Since the polarity of the contribution of the sampled offset signal to the output signal at the circuit output is swapped once the first mode or second mode is entered after having been in the second or first mode, respectively, the transition time from one mode to another has the same effect as continuing operation in said one mode. Ensuring that the first time interval(s) and second time interval(s) sum to substantially the same value as the third time interval(s) and fourth time interval(s) renders it possible to substantially average out the contribution of the sampled offset signal to the output of the circuit.

The input chopper and the output chopper may each be further operable in an open mode in which the input chopper and the output chopper are configured to disconnect the input thereof from the output thereof. In that case, the control unit may be configured to control the input chopper and the output chopper to operate in the open mode during at least one of the second time intervals (T2) and/or at least one of the fourth time intervals. Preferably, transitioning from the first mode to the second mode and/or transitioning from the second mode to the first mode may correspond to operating in the open mode. In a further embodiment, the control unit may be configured to control the input chopper and the output chopper to operate in the open mode while the auto-zeroing amplifier is controlled to operate in the auto-zeroing phase.

At least one but preferably all of the second time interval(s) and fourth time interval(s) may be substantially equal to a duration of auto-zeroing phase operation of the auto-zeroing amplifier.

The control unit may be configured to provide an auto-zeroing control signal to the auto-zeroing amplifier for controlling the auto-zeroing amplifier, and to provide a chopper control signal to the input chopper and the output chopper for controlling said input chopper and output chopper. In a further embodiment, a fundamental period of the auto-zeroing control signal may be n times a fundamental period of the chopper control signal. Here, n may be a multiple of 0.5, and may preferably be 1 or 2.

Each first time interval is substantially identical to a respective third time interval. Additionally or alternatively, each second time interval may be substantially identical to a respective fourth time interval. Additionally or alternatively, each first time interval may be substantially identical. Additionally or alternatively, each second time interval may be substantially identical. Additionally or alternatively, each third time interval may be substantially identical. Additionally or alternatively, each fourth time interval may be substantially identical.

Alternatively to the above embodiments, the first time interval(s) may be longer than the third time interval(s), and the fourth time interval(s) may be longer than the second time interval(s). Alternatively, the third time interval(s) may be longer than the first time interval(s), and the second time interval(s) may be longer than the fourth time interval(s).

The input chopper and output chopper may be differential components, each comprising first switches for enabling first mode operation, and second switches for enabling second mode operation.

The amplifier may be configured to amplify a signal received at an input of the amplifier and to provide the amplified signal at an output of the amplifier. In addition, during the auto-zeroing phase, the auto-zeroing circuitry may be configured to short the input of the amplifier and sample the offset signal at the output of the amplifier, and, during the output phase, the auto-zeroing amplifier may be configured to provide the auto-zeroed output signal by combining the amplified signal and the sampled offset signal.

The auto-zeroing circuitry may comprise a sample-and-hold unit for sampling the offset signal, one or more input switches for shorting the input of the amplifier during the auto-zero phase, and one or more output switches for electrically connecting the output of the amplifier to the sample-and-hold unit during the auto-zero phase.

The auto-zero amplifier may be further operable in a dummy auto-zero phase during which the auto-zero circuitry or dummy auto-zero circuitry is configured to short both the input of the amplifier and the output of the amplifier. In that case, the control unit may be configured to control the auto-zeroing amplifier to alternatingly operate in the auto-zero phase followed by the output phase, and dummy auto-zero phase followed by the output phase.

In a further embodiment, the control unit may be configured to control the auto-zeroing amplifier such that a duration of the auto-zeroing phase is substantially equal to a duration of the dummy auto-zeroing phase.

The one or more input switches may be configured to short the input of the amplifier while the auto-zeroing amplifier is operating in the dummy auto-zeroing mode. Alternatively, the dummy auto-zeroing circuitry may comprise one or more further input switches configured to short the input of the amplifier while the auto-zeroing amplifier is operating in the dummy auto-zeroing mode.

The auto-zeroing circuitry or the dummy auto-zero circuitry may comprise one or more further output switches configured to short the output of the amplifier while the auto-zeroing amplifier is operating in the dummy auto-zeroing mode.

The control unit may be configured to control the input chopper and the output chopper to operate in the open mode while the auto-zeroing amplifier is operating in the dummy auto-zeroing phase.

The circuit may further comprise one or more further amplifying stages electrically connected between the output chopper and the circuit output.

The one or more further amplifying stages comprises an integrator, such as a Miller-compensated amplifier stage.

The auto-zeroing amplifier may be configured for amplifying low-frequency signals. The circuit may further comprise an auxiliary amplifier electrically connected in parallel to the input chopper, the auto-zeroing amplifier and the output chopper. The auxiliary amplifier may be configured for amplifying high-frequency signals.

A ratio of a duration of the auto-zeroing phase and a total duration of the time period may be less than 0.1, preferably less than 0.05, more preferably less than 0.02.

The circuit may further comprise a first capacitive unit electrically connected between the input chopper and the input of the amplifier, a feedback chopper electrically connected between the circuit output and the input of the amplifier, a second capacitive unit electrically connected between the feedback chopper and the input of the amplifier, and a biasing unit configured to, only during auto-zeroing phase operation among auto-zeroing phase operation and output phase operation, apply a biasing voltage across the first capacitive unit. Furthermore, the control unit may be configured to control the feedback chopper synchronously with the input chopper and the output chopper.

The biasing unit may comprise a first switching unit configured to apply a first biasing voltage to a first terminal of the first capacitive unit electrically connected to the input of the amplifier. The first biasing voltage may be a reference voltage, such as ground.

The one or more input switches of the auto-zeroing circuitry described further above may be formed by the first switching unit. In other words, the first switching unit may be configured to short the input of the amplifier during the auto-zeroing phase.

Alternatively to the above first switching unit, the biasing unit may comprise a feedback switching unit. The feedback switching unit may be configured to apply the offset signal as at least part of a first biasing voltage to a first terminal of the first capacitive unit electrically connected to the input of the amplifier. The first capacitive unit may then be configured to store charge corresponding to the offset signal during auto-zeroing phase operation of the auto-zeroing amplifier and to substantially maintain said charge during output phase operation to thereby compensate the offset of the amplifier. The feedback switching unit and the first capacitive unit may together form the auto-zeroing circuitry.

Conveniently, in the above embodiment, the first capacitive unit can be used as sampling capacitors and can compensate or mitigate the offset of the amplifier via capacitive coupling. This eliminates the need for a separate sampling capacitor as well as various associated circuitry of the sample-and-hold unit. Moreover, the offset signal can be conveniently applied at the same time as the biasing voltage during the auto-zeroing phase.

To apply the offset signal as at least part of the first biasing voltage, the feedback switching unit may be configured to form a feedback loop for the amplifier during auto-zeroing phase operation.

The biasing unit may comprise a second switching unit configured to apply, during the auto-zeroing phase, a second biasing voltage to a second terminal of the first capacitive unit electrically connected to the input chopper. For example, the second biasing voltage may be a reference voltage or a common-mode voltage of an input signal received at the circuit input.

The biasing unit may comprise a third switching unit configured to apply, during the auto-zeroing phase, a third biasing voltage to a second terminal of the second capacitive unit electrically connected to the feedback chopper. For example, the third biasing voltage may be a reference voltage or a common-mode voltage at the circuit output.

According to another aspect of the present disclosure, a method for operating a circuit is provided. The circuit has a circuit input and a circuit output, and further comprises an auto-zeroing amplifier comprising an amplifier and auto-zeroing circuitry, and being operable in an auto-zeroing phase in which the auto-zeroing circuitry is configured to sample an offset signal of the amplifier, the offset signal being indicative of an offset of the amplifier, and an output phase in which the auto-zeroing circuitry is configured to provide an auto-zeroed output signal corresponding to an output signal of the amplifier combined with said sampled offset signal. The circuit further comprises an input chopper electrically connected between the circuit input and an input of the auto-zeroing amplifier, and an output chopper electrically connected between the output of the auto-zeroing amplifier and the circuit output.

The method according to the present disclosure comprises controlling the auto-zeroing amplifier, the input chopper and the output chopper such that, over a time period from entering output phase operation to again entering the output phase operation following the auto-zero phase operation, the sampled offset signal in the auto-zeroed output signal is substantially averaged out at the circuit output.

Further steps and control functions carried out by the control unit of the circuit in the above-described aspect may equally apply as method steps in the present method for operating a circuit.

According to yet another aspect of the present disclosure, a circuit is provided having a circuit input and a circuit output. The circuit comprises an auto-zeroing amplifier including an amplifier and auto-zeroing circuitry, an output of the auto-zeroing amplifier being either directly or indirectly electrically connected to the circuit output. The auto-zeroing amplifier is operable in an auto-zeroing phase and in an output phase. In the auto-zeroing phase, the auto-zeroing circuitry is configured to sample an offset signal of the amplifier, the offset signal being indicative of an offset of the amplifier. In the output phase, the auto-zeroing amplifier is configured to provide an auto-zeroed output signal towards the circuit output, the auto-zeroed output signal corresponding to an output signal of the amplifier combined with said sampled offset signal.

The circuit further comprises a first capacitive unit electrically connected between the circuit input and an input of the amplifier, a second capacitive unit electrically connected between the circuit output and the input of the amplifier, and a biasing unit configured to, only during the auto-zeroing phase among the auto-zeroing phase and the output phase, apply a biasing voltage to the first capacitive unit.

In conventional capacitively coupled amplifiers, biasing at the input of the amplifier is provided by means of a reference voltage connected to the input of the amplifier via a resistor. In view of bandwidth requirements, this resistor is typically relatively large. As a result, it can also significantly contribute to the noise of the circuit.

By contrast, in the circuit according to the present aspect of the present disclosure, an auto-zeroing amplifier is used which is operable in an auto-zeroing phase and in an output phase. By only providing the biasing voltage in the auto-zeroing phase, the first capacitive unit can maintain the stored charge during the output phase, during which input signals are processed. Therefore, in addition to offset compensation, the auto-zeroing amplifier provides a useful period of time during which biasing can be provided by the biasing unit without or with hardly any influence on the signal processing.

The biasing unit may comprise a first switching unit configured to apply a first biasing voltage to a first terminal of the first capacitive unit electrically connected to the input of the amplifier. The first biasing voltage may be a reference voltage, such as ground.

In a further embodiment, the auto-zeroing circuitry may comprise a sample-and-hold unit configured to sample the offset signal during the auto-zeroing phase and to provide the sampled offset signal during the output phase, and one or more output switches configured to electrically connect the amplifier to the sample-and-hold unit during the auto-zeroing phase. In that case, the first switching unit may be configured to short the input of the amplifier during the auto-zeroing phase.

Alternatively, the biasing unit may comprise a feedback switching unit configured to apply the offset signal as at least part of a first biasing voltage to a first terminal of the first capacitive unit electrically connected to the input of the amplifier. In that case, the first capacitive unit may be configured to store charge corresponding to the offset signal during auto-zeroing phase operation of the auto-zeroing amplifier and to substantially maintain said charge during output phase operation to thereby compensate the offset of the amplifier during output phase operation. The feedback switching unit and the first capacitive unit may thus together form the auto-zeroing circuitry. By using the first capacitive unit also as a sampling capacitor for the offset signal and using the corresponding stored charge to compensate or mitigate the offset of the amplifier, a more compact implementation can be achieved, since there is no need for a separate sample-and-hold unit.

To apply the offset signal as at least part of the first biasing voltage, the feedback switching unit may be configured to form a feedback loop for the amplifier during auto-zeroing phase operation.

The biasing unit may comprise a second switching unit configured to apply, during the auto-zeroing phase, a second biasing voltage to a second terminal of the first capacitive unit either directly or indirectly electrically connected to the circuit input. For example, the second biasing voltage may be a reference voltage or a common-mode voltage of an input signal received at the circuit input.

The biasing unit may comprise a third switching unit configured to apply, during the auto-zeroing phase, a third biasing voltage to a second terminal of the second capacitive unit either directly or indirectly electrically connected to the circuit output. For example, the third biasing voltage may be a reference voltage or a common-mode voltage at the circuit output.

The circuit may further comprise an input chopper electrically connected between the circuit input and the first capacitive unit, an output chopper electrically connected between an output of the auto-zeroing amplifier and the circuit output, and a feedback chopper electrically connected between the circuit output and the input of the amplifier.

In a further embodiment, the input chopper, the output chopper and the feedback chopper may each be operable in a first mode, in which said chopper is configured to multiply an input signal thereof by +1 or to directly couple an input thereof to an output thereof, and a second mode, in which said chopper is configured to multiply an input signal thereof by −1 or to cross-couple an input thereof to an output thereof. For example, the input chopper, the output chopper and the feedback chopper may be configured to alternatingly operate in the first mode and second mode.

The circuit may further comprise a control unit configured to control the auto-zeroing amplifier, the input chopper, the output chopper, the feedback chopper, and the biasing unit.

Here, it is noted that the control unit in the present aspect of the present disclosure may be identical or similar to the control unit described above, in particular regarding controlling the auto-zeroing amplifier, the input chopper and the output chopper. In other words, the control unit may be configured to control the input chopper, output chopper and feedback chopper such that, in a time period from the auto-zeroing amplifier entering output phase operation to again entering output phase operation following the auto-zero phase operation, the sampled offset signal in the auto-zeroed output signal is substantially averaged out at the circuit output.

All further embodiments of the control unit and other elements of the circuit described in the aforementioned aspects of the present disclosure may equally apply to the present aspect.

According to another aspect of the present disclosure, a method for controlling a circuit is provided. The circuit comprises an auto-zeroing amplifier including an amplifier and auto-zeroing circuitry, an output of the auto-zeroing amplifier being either directly or indirectly electrically connected to the circuit output. The auto-zeroing amplifier is operable in an auto-zeroing phase and in an output phase. In the auto-zeroing phase, the auto-zeroing circuitry is configured to sample an offset signal of the amplifier, the offset signal being indicative of an offset of the amplifier. In the output phase, the auto-zeroing amplifier is configured to provide an auto-zeroed output signal towards the circuit output, the auto-zeroed output signal corresponding to an output signal of the amplifier combined with said sampled offset signal. The circuit further comprises a first capacitive unit electrically connected between the circuit input and an input of the amplifier, a second capacitive unit electrically connected between the circuit output and the input of the amplifier, and a biasing unit. The method comprises controlling the biasing unit to, only during the auto-zeroing phase among the auto-zeroing phase and the output phase, apply a biasing voltage to the first capacitive unit.

The circuit may be that of the previously described aspect and the method may further comprise control steps in accordance with the control of circuit as described above.

### DETAILED DESCRIPTION

Next, the present disclosure will be described in more detail referring to the appended drawings, wherein:

FIG. 1A is a schematic diagram of a circuit known in the art with offset compensation using chopper stabilization;

FIG. 1B is a schematic diagram of a circuit known in the art with offset compensation using auto-zeroing;

FIG. 1C is a schematic diagram of a circuit known in the art with offset compensation using both auto-zeroing and chopper stabilization;

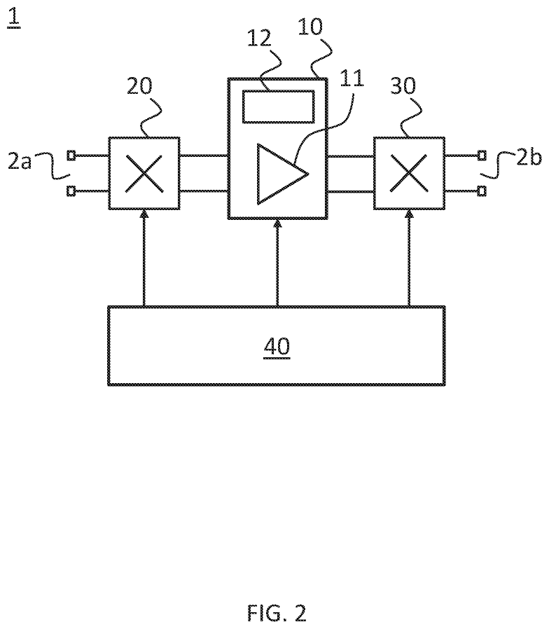

FIG. 2 is a schematic diagram of a circuit according to an embodiment of the present disclosure;

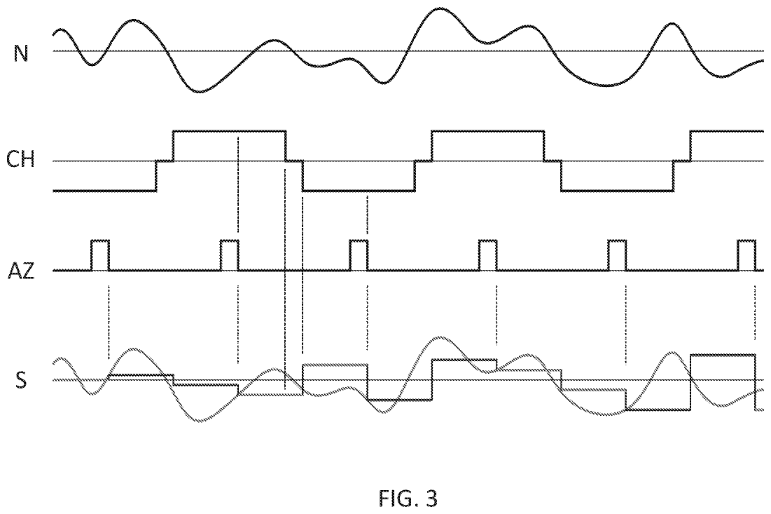

FIG. 3 is a signal diagram illustrating sampling during an auto-zeroing phase and output phase of the circuit of FIG. 2;

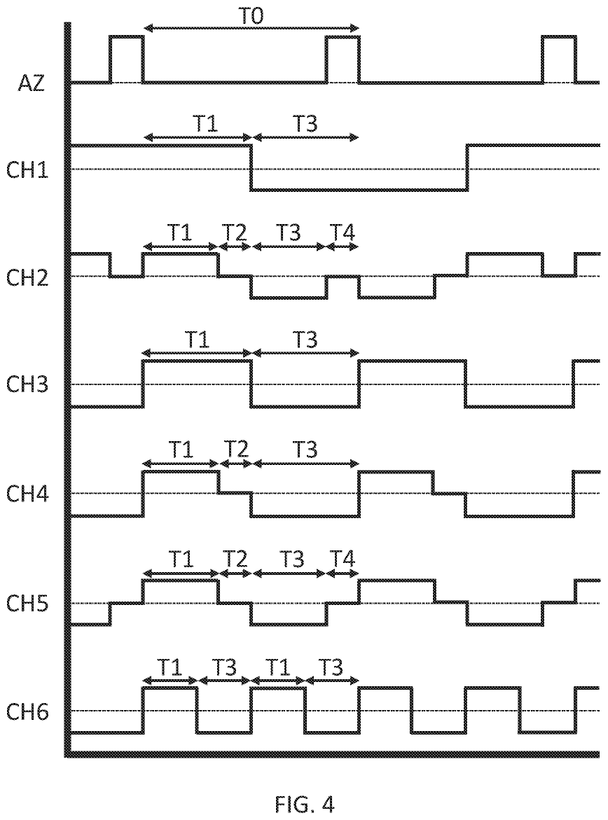

FIG. 4 is a state diagram illustrating operating states of the input chopper, output chopper and auto-zeroing amplifier of the circuit of FIG. 2;

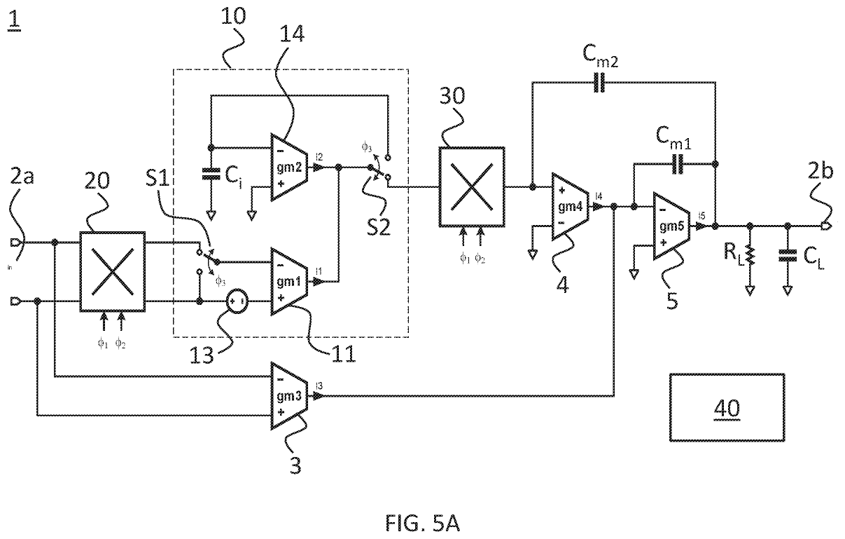

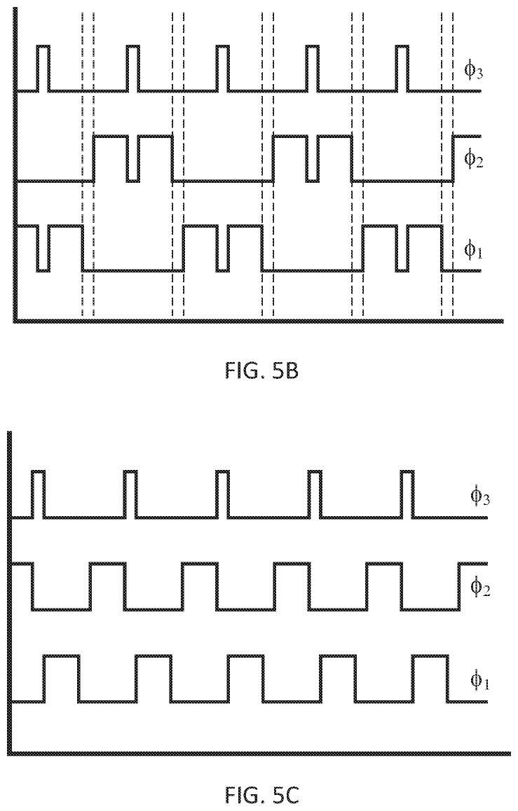

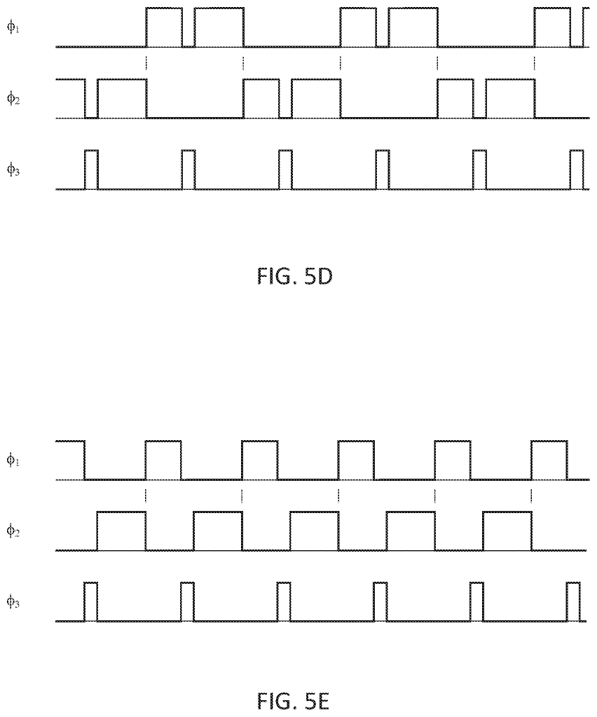

FIG. 5A is schematic diagram of a circuit according to an embodiment of the present disclosure;

FIG. 5B-5E are signal diagrams illustrating control signals for controlling the circuit of FIG. 5A;

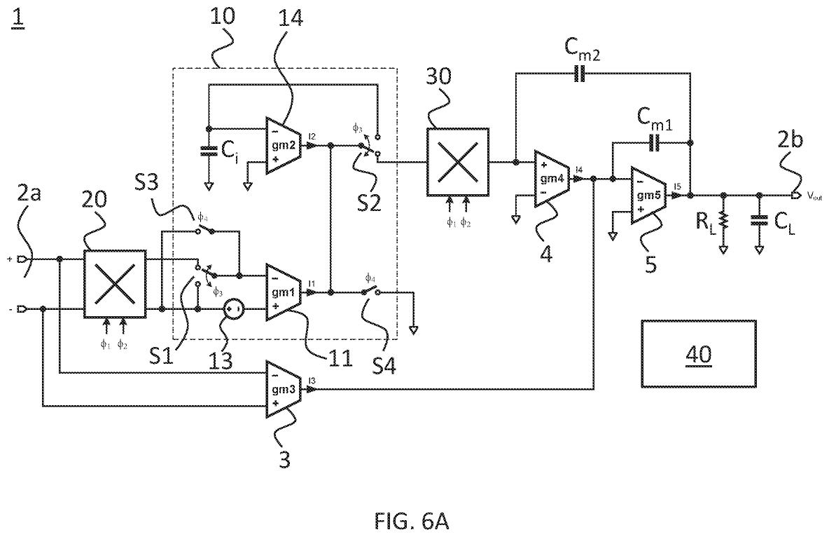

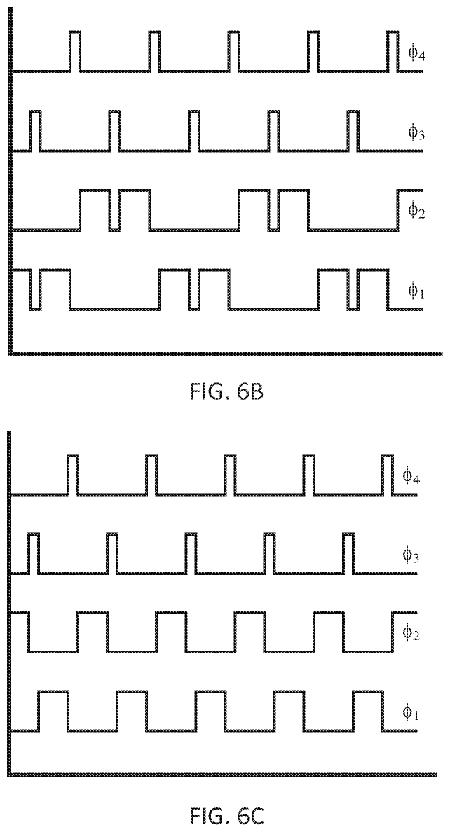

FIG. 6A is a schematic diagram of a circuit according to another embodiment of the present disclosure;

FIGS. 6B and 6C are signal diagrams illustrating control signals for controlling the circuit of FIG. 6A;

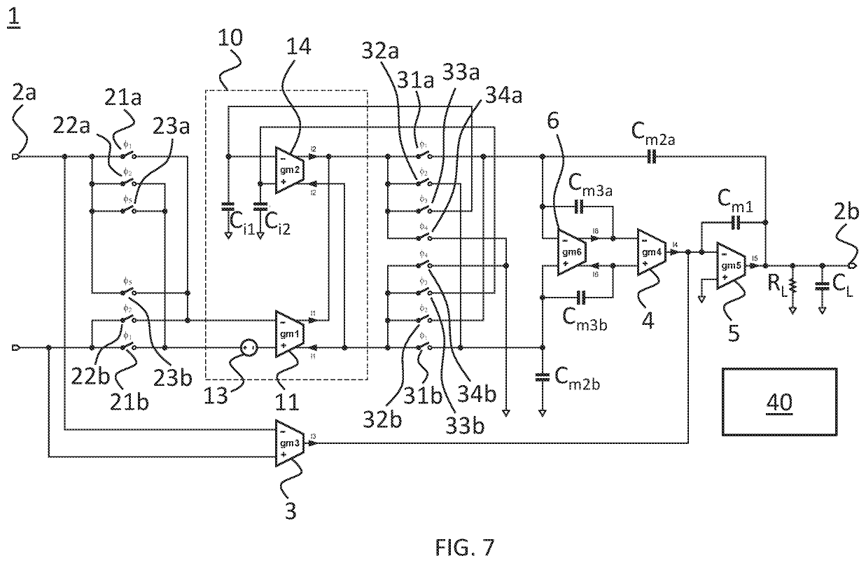

FIG. 7 is a schematic diagram of a circuit according to another embodiment of the present disclosure;

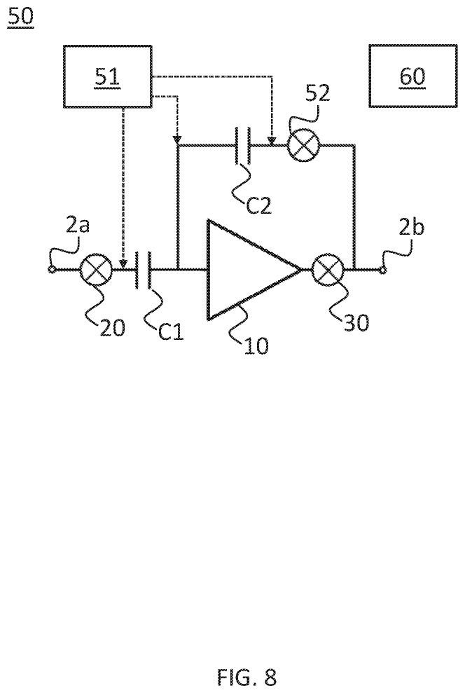

FIG. 8 is a schematic diagram of a circuit according to another embodiment of the present disclosure; and

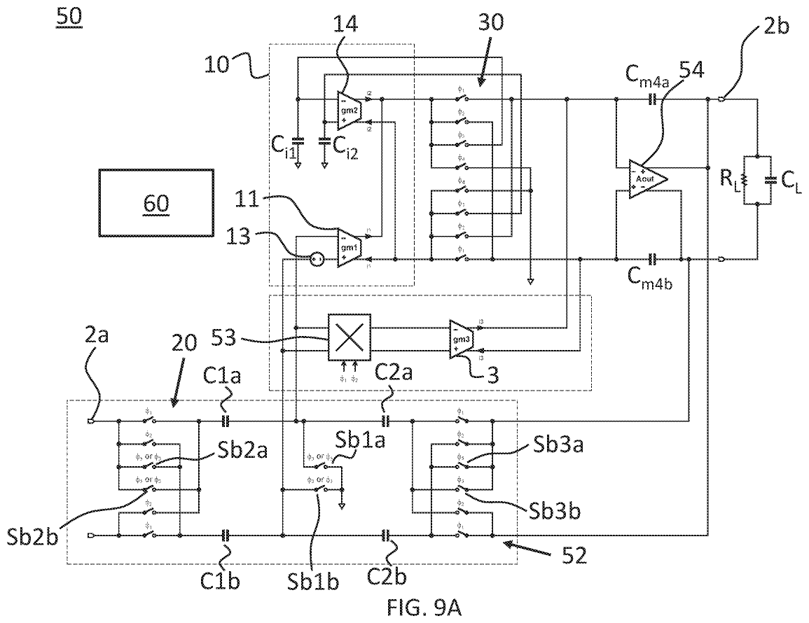

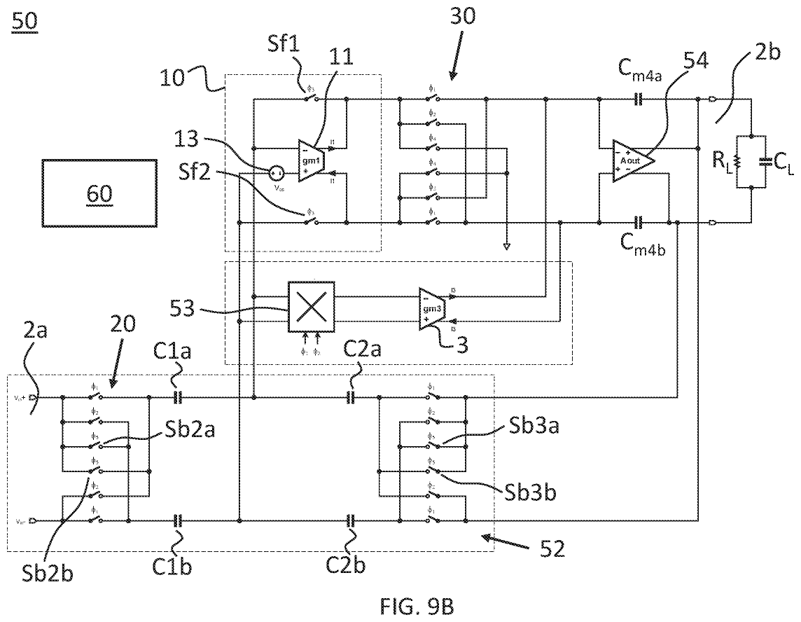

FIGS. 9A and 9B are schematic diagrams of a circuit according to embodiments of the present disclosure.

The present disclosure is described in conjunction with the appended figures. It is emphasized that, in accordance with standard practice in the industry, various features are not drawn to scale. In fact, the dimensions of the various features may be arbitrarily increased or reduced for clarity of discussion.

FIG. 2 illustrates a circuit 1 according to an embodiment of the present disclosure. Circuit 1 has a circuit input 2a and a circuit output. Input signals can be received at circuit input 2a, and a processed input signal, having been processed by circuit 1, can be output at circuit output 2b.

Circuit 1 comprises an auto-zeroing amplifier 10 including an amplifier 11 and auto-zeroing circuitry 12. Here, a detailed view of auto-zeroing amplifier 10 is omitted from FIG. 2. Nevertheless, auto-zeroing amplifier 10 may have an identical or similar structure as auto-zeroing amplifier 100b shown in FIG. 1B, or other known auto-zeroing amplifier structures and amplifiers employing an auto-zeroing technique for offset compensation.

Circuit 1 further comprises an input chopper 20 and an output chopper 30, which may be identical or similar to input chopper 102a and output chopper 102b, respectively, as shown in FIG. 1A or FIG. 1C.

Although FIG. 2 illustrates circuit 1 as a fully differential circuit, this need not be the case. Instead, part or all of circuit 1 may be implemented as a single-ended structure. For example, amplifier 11 may have differential input terminals and a single-ended output terminal.

As described with reference to FIG. 1A, input chopper 20 and output chopper 30 may be operable in a first mode and a second mode. In the first mode, in the case of a single-ended implementation, input chopper 20 and output chopper 30 may be configured to (effectively) multiply a signal at its input by +1 and output the result, and, in the case of a differential implementation, input chopper 20 and output chopper 30 may be configured to directly couple its input and output. In the second mode, in the case of a single-ended implementation, input chopper 20 and output chopper 30 may be configured to (effectively) multiply the signal at its input by −1 and output the result, and, in the case of a differential implementation, input chopper 20 and output chopper 30 may be configured to cross-couple its input and output. Here directly coupling and cross-coupling correspond to connecting its input and output in a way that achieves either a same polarity or a different polarity of the output signal of said chopper with respect to its input signal. Input chopper 20 and output chopper 30 may be operated synchronously. In other words, they may always be controlled to operate in a same operating mode.

Additionally, input chopper 20 and output chopper 30 may optionally be operable in a third mode, such as an open mode. In the open mode, for example, the input of input chopper 20 or output chopper 30 may be electrically disconnected from the output thereof. In a single-ended implementation, this may correspond to a multiplication by zero, or may also imply that the input and output are disconnected, such as by a switch (not shown).

As described with reference to FIG. 1B, auto-zeroing amplifier is operable in an auto-zeroing phase and an output phase.

In the auto-zeroing phase, auto-zeroing circuitry 12 is configured to sample an offset signal of amplifier 11. Here, the offset signal is a signal representing the offset of amplifier 11. This may, for example, be achieved by shorting the amplifier input and sampling a signal at the amplifier output. In that case, the offset signal corresponds to an amplified input-referred offset of amplifier 11. It is noted that the offset signal may also inherently include noise, such as thermal noise. As a result, the sampled offset signal may also inherently include a sampled instantaneous value of the noise at the moment of sampling.

In the output phase, the sampled offset signal is combined with a signal at the amplifier output to form the output signal of auto-zeroing amplifier 10. In doing so, the sampled offset signal can compensate or mitigate the offset component in the output signal of the amplifier, irrespective of the presence of an input signal at circuit input 2a. Auto-zeroing circuitry 12 may comprise a sample-and-hold unit (not shown in FIG. 2) for sampling the offset signal in the auto-zeroing phase and for providing the sampled offset signal in the output phase.

A control unit 40 is included in circuit 1 for controlling auto-zeroing amplifier 10, input chopper 20 and output chopper 30. Control unit 40 can bring input chopper 20 and output chopper 30 into the first mode, the second mode or, if applicable, the open mode. This may be achieved using one or more chopper control signals, as will be described further below with reference to FIG. 5A-5C. Input chopper 20 and output chopper 30 may be synchronously operated by control unit 40. Control unit 40 can also control auto-zeroing amplifier 10 to operate in the auto-zeroing phase or the output phase. This may be achieved using one or more auto-zeroing control signals.

The control of auto-zeroing amplifier 10, input chopper 20 and output chopper 30 can highly affect the performance of circuit 1. In particular, although auto-zeroing circuitry 12 ideally samples only a signal exactly reflecting the offset of amplifier 11, in practice, the offset signal will include noise as well, and an instantaneous noise value may be included in the sampled offset signal. This instantaneous noise value is subsequently held by auto-zeroing circuitry 12 in the output phase and is thus included in the output signal of auto-zeroing amplifier 10. Noise and offset are both key parameters in circuits, especially in amplifier circuits and moreover for the input stage of the amplifier circuits, since the input signal is typically the smallest at the input stage and thus the relative effect of offset and noise at said input stage is the greatest. Hence, amplifier 11 may correspond to an input stage of an amplifier system. Although not shown in FIG. 2, circuit 1 may optionally further include further amplifying stages or other circuitry such as filtering circuitry, electrically connected between output chopper 30 and circuit output 2b.

To eliminate or suppress the noise sampling effect, control unit 40 is configured to control auto-zeroing amplifier 10, input chopper 20 and output chopper 30 such that, in a time period from entering output phase operation to again entering the output phase operation following the auto-zero phase operation, the sampled offset signal in the output signal of auto-zeroing amplifier 10 is substantially averaged out at circuit output 2b. Since output chopper 30 can swap the polarity of the output signal of auto-zeroing amplifier 10 towards circuit output 2b, output chopper 30 can be controlled such that the contribution of both the offset and noise can be substantially averaged out over said time period from the start of output phase operation to the start of subsequent output phase following auto-zeroing phase operation. Again, since the offset of amplifier 11 is not affected by input chopper 20, even any mismatch between the sampled offset signal and the actual amplifier offset can be eliminated or suppressed by the abovementioned control.

The abovementioned control by control unit 40 may be especially relevant when circuit 1 includes reactive elements between auto-zeroing amplifier 10 and circuit output 2b. For example, circuit 1 may be used to drive a (at least partially) capacitive load, or further circuitry (not shown) including capacitive elements may be included in between output chopper 30 and circuit output 2b. In that case, when auto-zeroing amplifier 10 switches to the auto-zeroing phase, and/or when output chopper 30 operates in the open mode, an effective sampling of the output signal of auto-zeroing amplifier 10 may occur at circuit output 2b, at said further circuitry, or at both. As a result, the noise at the output of circuit 1 is increased.

Control unit 40 and its control of auto-zeroing amplifier 10, input chopper 20 and output chopper 30 as described above, in particular by looking at the time period described above and ensuring that over said time period the offset signal is substantially averaged out, ensures that offset and noise is effectively suppressed regardless of a load of circuit 1 or subsequent circuitry following output chopper 30. Hence, circuit 1 exhibits more flexibility as well as improved key parameters such as offset and noise.

FIG. 3 illustrates a simplified signal diagram including a noise signal N at the output of auto-zeroing amplifier 10, a chopper signal CH representing operational modes of output chopper 30, an auto-zeroing signal AZ representing operational phases of auto-zeroing amplifier 10, and an output signal S of circuit 1. For convenience, the signal diagram of FIG. 3 assumes no input signal to circuit 1.

Noise signal N may be a (zero-mean) Gaussian noise signal caused by, for example, thermal noise. Noise signal N may instead also reflect a combination of both offset and noise at the output of amplifier 11.

Chopper signal CH illustrates operation in the first mode, the open mode and the second mode respectively using a high level, a medium level and a low level. Auto-zeroing signal AZ illustrates operation in the auto-zeroing phase and output phase using a high and low level, respectively. In the signal diagram corresponding to output signal S, the noise signal is additionally shown overlaying output signal S for convenience of explanation.

During auto-zeroing phase operation, the output signal of amplifier 11 is sampled by auto-zeroing circuitry 12. At the end of auto-zeroing phase operation this sampled signal is substantially fixed and remains fixed for the duration of the output phase until the next auto-zeroing phase starts. As a result, output signal S (in absence of an input signal to circuit 1) is also at a fixed level corresponding to the sampled value. When output chopper 30 switches from the first mode to the second mode or vice versa, the fixed level in output signal S also switches polarity.

However, as shown in FIG. 3, operating in the open mode does not affect the polarity of output signal S. Only when output chopper 30 enters the first mode or second mode does the polarity switch with respect to the other mode. This effect is due to sampling by reactive elements following output chopper 30, such as a capacitive load or further circuitry. As a result, operating in the open mode following first mode operation, from the perspective of circuit output 2b, has the same effect as continued operation in the first mode. Similarly, operating in the open mode following second mode operation has the same effect as continued operation in the second mode.

To average out the noise and offset, it should be ensured that output chopper 30 operates in the correct operating mode for a correct duration of time. Switching from the first mode to the second mode or vice versa may be performed substantially instantaneously (i.e., no downtime), or may instead be performed by temporarily operating in the open mode. The duration of operating in the first mode, second mode and open mode should be taken into account to ensure that noise and offset is averaged out at circuit output 2b.

FIG. 4 illustrates a state diagram of auto-zeroing amplifier 10 using auto-zeroing signal AZ reflecting operational phases of auto-zeroing amplifier 10, and of input chopper 20 and output chopper 30 using one of chopper signals CH1-CH6 reflecting operational modes of input chopper 20 and output chopper 30.

The total duration from the start of output phase operation to the start of subsequent output phase operation following auto-zeroing mode operation may be equal to T0. In chopper signals CH1-CH6, first time intervals T1, second time intervals T2, third time intervals T3 and fourth time intervals T4 may be defined. First time intervals T1 may correspond to an interval during which output chopper 30 operates in the first mode. Second time intervals T2 may correspond to an interval during which output chopper 30 transitions from the first mode to the second mode, or operates in the open mode following first mode operation. Third time intervals T3 may correspond to an interval during which output chopper 30 operates in the second mode. Fourth time intervals T4 may correspond to an interval during which output chopper 30 transitions from the second mode to the first mode, or operates in the open mode following second mode operation. To achieve noise (and offset) suppression, in accordance with the above, it should be ensured that T1+T2=T3+T4.

In some embodiments, some or all second time intervals T2 and fourth time intervals T4 may be about zero, representing a substantially instantaneous transition from the first mode to the second mode or vice versa. This is for example shown in chopper signals CH1, CH3, CH4 and CH6. In chopper signal CH4, a second time interval T2 is included but the fourth time interval is about zero.

Within time period T0, multiple first time intervals T1, second time intervals T2, third time intervals T3 and fourth time intervals T4 may be included. This is for example illustrated using chopper signal CH6. Here, although second time intervals T2 and fourth time intervals T4 are omitted, they may equally be applied to embodiments including multiple first time intervals T1 and/or second time intervals T2 in the time period T0.

Moreover, although not illustrated in FIG. 4, first time intervals T1 need not have the same length within time period T0. Similarly, second time intervals T2, third time intervals T3, and fourth time intervals T4 need not have the same length.

A fundamental period of the operation of input chopper 20 and output chopper 30 may be n times the period of the operation of auto-zeroing amplifier 10 (i.e., time period T0). Here, n may be a multiple of 0.5. However, in order to minimize switching, n is preferably 1, such as in chopper signals CH1 and CH2, or 2, such as in chopper signals CH3, CH4 and CH5.

FIG. 5A illustrates a more detailed schematic diagram of circuit 1 according to an embodiment of the present disclosure.

In addition to auto-zeroing amplifier 10, input chopper 20, output chopper 30 and control unit 40, circuit 1 may further comprise an auxiliary amplifier 3, a first further amplifier 4, and a second further amplifier 5. Circuit 1 is configured to receive input signals at circuit input 2a, and to output a processed input signal at circuit output 2b. In this embodiment, circuit output 2b is connected to a load including a load resistance RL and a load capacitance CL. For convenience, electrical connections between control unit 40 and remaining components of circuit 1 are omitted from FIG. 5A.

First further amplifier 4 and second further amplifier 5 are in this embodiment realized using transconductors gm4 and gm5, respectively. Since the input signal is already amplified by auto-zeroing amplifier 10 by the time it reaches the input of first further amplifier 4, the contribution of first further amplifier 4 and second further amplifier 5 to offset and noise at circuit output 2b is relatively low. In this embodiment, Miller capacitors Cm1 and Cm2 are included for frequency compensation (i.e., bandwidth improvement) of the first further amplifier 4 and second further amplifier 5, as will be appreciated by a person skilled in the art.

In this embodiment, first further amplifier 4 and second further amplifier 5 form an integrating amplifier stage, driven by the earlier amplifier stage formed by auto-zeroing amplifier 10. Miller capacitor Cm2 is capacitive (i.e., reactive), such that sampling effectively occurs on during auto-zeroing phase operation or open mode operation. However, control unit 40 can ensure that the offset and noise is nevertheless substantially averaged out at circuit output 2b.

Auto-zeroing amplifier 10, input chopper 20 and output chopper 30 may periodically interrupt the signal path from circuit input 2a to circuit output 2b. As a result, the signal path provided via auto-zeroing amplifier 10 may be suited for low-frequency signals rather than high-frequency signals. To accommodate high-frequency signals as well, auxiliary amplifier 3 is provided, realized in this embodiment as transconductor gm3. Since offset is low-frequency and almost static. Since auxiliary amplifier 3 is arranged in parallel to auto-zeroing amplifier 10 and, in this embodiment, first further amplifier 4, its contribution to the total input-referred offset is relatively low. Moreover, since offset is typically at DC or varies only slowly, filtering can be applied in the case of high-frequency signals to remove the effect of the offset in circuit 1.

In this embodiment, auto-zeroing amplifier 10 includes amplifier 11 having an input-referred offset voltage 13. The auto-zeroing circuitry of amplifier 10 includes input switch S1, output switch S2, comparing unit 14 and sampling capacitor Ci. In this embodiment, comparing unit 14 is realized using transconductor gm2. Comparing unit 14, sampling capacitor Ci and output switch S2 may together form a sample-and-hold unit.

In the auto-zeroing phase, input switch S1 may short the input of amplifier 11, and output switch S2 may connect the output of amplifier 11 to sampling capacitor Ci and the input of comparing unit 14. As a result, a feedback loop is formed by comparing unit 14 and output switch S2. Current I1 from amplifier 11 is fed into sampling capacitor Ci, thereby changing the voltage across it. This voltage in turn causes a change in a current I2 output by comparing unit 14. Currents I1 and I2 are combined at a combining unit 15, in this case simply an electric node. Since currents I1 and I2 are both fed into sampling capacitor Ci, due to the negative feedback configuration, the voltage across sampling capacitor Ci will change until currents I1 and I2 are equal. At this stage, since current I1 output by amplifier 11 corresponds to the offset signal, current I2 also reflects the offset signal. In the output phase, input switch S1 may connect input chopper 20 to auto-zeroing amplifier 10 and output switch S2 may connect auto-zeroing amplifier 10 to output chopper 30, thereby restoring the signal path from circuit input 2a to circuit output 2b. By interrupting the feedback loop with output switch S2, the voltage across sampling capacitor Ci remains substantially fixed during the output phase. As a result, current I2 reflecting the offset signal is summed with the output signal from amplifier 11 to compensate for offset 13.

The signal path from amplifier 11 to circuit output 2b may be interrupted by output switch S2 during the auto-zeroing phase. However, this need not be the case. Instead or in addition, output chopper 30 may operate in the open mode, thereby disconnecting its input and output. In that case, output switch S2 may simply connect or disconnect a sample-and-hold unit to or from the amplifier output, and the amplifier output may then always be connected to output chopper 30. It will be appreciate that the signal path is interrupted for the purpose of sampling the amplifier output without interference or loading of the amplifier output by external elements not part of the sampling means. Similarly, during the auto-zeroing phase, the signal path from circuit input 2a to amplifier 11 may be shorted by input switch S1, or interrupted by input chopper 20, or both, for the purposes of sampling the offset signal.

It will be appreciated by the skilled person that the implementation of auto-zeroing amplifier 10 and its functionality described above is merely exemplary, and other known configurations are equally envisaged by the present disclosure.

Input chopper 20 and output chopper 30 may be controlled by control unit 40 using a first chopper control signal φ₁ and a second chopper control signal φ₂. For example, first chopper control signal φ₁ and second chopper control signal φ₂ may both be digital signals implementing a binary control. If first chopper control signal φ₁ is high and second chopper control signal φ₂ is low, then input chopper 20 and output chopper 30 may operate in the first mode (e.g., the coupling mode). On the other hand, if second chopper control signal φ₂ is high and first chopper control signal φ₁ is low, then input chopper 20 and output chopper 30 may operate in the second mode (e.g., the cross-coupling mode). If both first chopper control signal φ₁ and second chopper control signal φ₂ are low, then input chopper 20 and output chopper 30 may operate in the open mode.

Similarly, auto-zeroing amplifier 10 may be controlled by control unit 40 using an auto-zeroing control signal φ₃, which in this case may actuate input switch S1 and output switch S2. For example, when auto-zeroing control signal φ₃ is high, auto-zeroing amplifier 10 may operate in the auto-zeroing phase, and when auto-zeroing control signal φ₃ is low, auto-zeroing amplifier 10 may operate in the output phase.

FIG. 5B-5E illustrate various examples of control signal schemes suitable for the circuit 1 of FIG. 5A. Each of FIG. 5B-5E implement the control conditions described with reference to FIG. 2-4. A detailed description thereof is therefore omitted.

As shown in FIG. 5B, control unit 40 controls input chopper 20 and output chopper 30 to operate in the open mode during the auto-zeroing phase, as well as during part of a transition from the first mode to the second mode and vice versa. This allows control unit 40 to easily generate first chopper control signal φ₁ and second chopper control signal φ₂ as a signal with an identical but phase-shifted pattern. The fundamental frequency of input chopper 20 and output chopper 30 here is 0.5 times that of the auto-zeroing frequency, thereby minimizing switching. Here, the operating mode of input chopper 20 and output chopper 30 is the same before and after a given auto-zeroing phase. Here, it is noted that input chopper 20 and output chopper 30 are shown as being controlled to operate in the open mode during auto-zeroing phase operation of auto-zeroing amplifier 10. However, this need not be the case. Instead, output switch S2 may disconnect the amplifier output from output chopper 30.

As shown in FIG. 5C, control unit 40 controls input chopper 20 and output chopper 30 to operate in the open mode during the auto-zeroing phase, as well as during part of a transition from the first mode to the second mode and vice versa. However, the control is different from FIG. 5B in that input chopper 20 and output chopper 30 have different operating modes before and after a given auto-zeroing phase.

As shown in FIG. 5D, instead of operating in the open mode outside of the auto-zeroing phase, a duration of operating in the first mode or second mode may be extended. Here, the first operating mode following auto-zeroing phase operation is extended with respect to the other mode among the first and second mode, since input chopper 20 and output chopper 30 operate in the open mode during the auto-zeroing phase. The operating mode before and after a given auto-zeroing phase is the same.

As shown in FIG. 5E, the first operating mode following the auto-zeroing phase is extended with respect to the other mode among the first and second mode. However, the control is different from FIG. 5D in that the operating mode before and after a given auto-zeroing phase is different.

It will be appreciated by the skilled person that the control signals shown in FIG. 5B-5E are merely exemplary, and that the present disclosure it not limited to any such example. Different implementations are envisaged as long as the control satisfies the requirements discussed with reference to FIG. 4. For example, first chopper control signal φ₁ and second chopper control signal φ₂ may be identical or similar to any of chopper signals CH1-CH6 shown in FIG. 3, or the like.

FIG. 6A illustrates another embodiment of circuit 1, which differs from FIG. 5A in that auto-zeroing amplifier 10 further includes a further input switch S3 and a further output switch S4. A detailed description of identical or similar elements already described with reference to FIG. 5A is omitted.

In this embodiment, auto-zeroing amplifier 10 may be further operable in a dummy auto-zeroing phase. In this phase, further input switch S3 shorts the input of amplifier 11, and further output switch S4 shorts the output of amplifier 11. The dummy auto-zeroing phase may be introduced to further improve the symmetry of operation of circuit 1. However, since in this phase the voltage across sampling capacitor Ci should not be changed, current I1 output by amplifier 11 is shorted to a reference terminal (e.g., ground) via further output switch S4. As a result, when auto-zeroing amplifier 10 is controlled to operate again in the output phase after operating in the dummy auto-zeroing phase, the offset compensation remains unchanged and is only adjusted in the auto-zeroing phase.

Control unit 40 may provide a dummy auto-zeroing control signal φ₄ to auto-zeroing amplifier 10 that actuates further input switch S3 and further output switch S4. For example, dummy auto-zeroing control signal φ₄ may be a digital signal implementing binary control. When high, dummy auto-zeroing control signal φ₄ closes further input switch S3 to short the input of amplifier 11 and closes further output switch S4 to short the output of amplifier 11. When low, dummy auto-zeroing control signal φ₄ opens further input switch S3 and further output switch S4.

Alternatively, the functionality of input switch S1 and further input switch S3 may be combined in a single input switch (not shown) that is actuated by control unit 40 for controlling auto-zeroing amplifier 10 to operate in either of the auto-zeroing phase and dummy auto-zeroing phase. In that case, for said single input switch, a separate control signal φ₅ (not shown) may be provided by control unit 40, said separate control signal φ₅ corresponding to a combination of auto-zeroing control signal φ₃ and dummy auto-zeroing control signal φ₄.

Control unit 40 may be configured to control auto-zeroing amplifier 10 to operate alternatingly in the auto-zeroing phase followed by the output phase, and in the dummy auto-zeroing phase followed by the output phase, which may both have a same or similar combined duration. In some embodiments, control unit 40 may control auto-zeroing amplifier 10 such that a duration of the dummy auto-zeroing phase is substantially equal to a duration of the auto-zeroing phase to further improve the electrical symmetry.

In particular, improving the electrical symmetry of circuit 1 with the introduction of dummy auto-zeroing phase operation allows substantially the same impedance to be presented to the input and output of amplifier 11 in the auto-zero phase and the dummy auto-zero phase, thereby avoiding or at least mitigating second-order effects which may otherwise deteriorate the accuracy of circuit 1, which may be especially relevant in precision applications. Such second-order effects that may otherwise occur (or to a greater extent) may include charge injection from the chopper switches, capacitance non-linearity, and/or crosstalk from other nodes in the circuit.

FIGS. 6B and 6C illustrate examples of control signal schemes suitable for circuit 1 of FIG. 5A, each implementing the control conditions described with reference to FIG. 2-4. A detailed description thereof is therefore omitted.

As shown in FIG. 6B, the control for circuit 1 of FIG. 6A may be similar to that of FIG. 5B, with the addition of dummy auto-zeroing control signal φ₄. Similarly, as shown in FIG. 6C, the control for circuit 1 of FIG. 6A may be similar to that of FIG. 5C, with the addition of dummy auto-zeroing control signal φ₄.

It will be appreciated by the skilled person that the control signals shown in FIGS. 6B and 6C are merely exemplary, and that the present disclosure it not limited to any such example. Different implementations are envisaged as long as the control satisfies the requirements discussed with reference to FIG. 4. For example, first chopper control signal φ₁, second chopper control signal φ₂ and auto-zeroing control signal φ₃ may be identical or similar to that shown in FIG. 5D or 5E. First chopper control signal φ₁ and second chopper control signal φ₂ may also be identical or similar to any of chopper signals CH1-CH6 shown in FIG. 3, or the like.

FIG. 7 illustrates circuit 1 according to another embodiment of the present disclosure, differing from the embodiment shown in FIG. 6A in that input chopper 20 and output chopper 30 are realized using switches and are arranged together with switches from auto-zero circuitry 12 in a switch bank. In other words, auto-zeroing circuitry 12 of FIG. 2 may at least partially be realized in an integrated structure together with input chopper 20 and/or output chopper 30. For example, output chopper 30 may simultaneously operate in the open mode, disconnecting its input and output, and connect the amplifier output to the sample-and-hold unit.

In addition, in the embodiment shown in FIG. 7, circuit 1 further comprises a third further amplifier 6 for realizing a structure known as a Hybrid Nested Miller Compensated amplifier, the miller compensation being realized using capacitors Cm1, Cm2a, Cm2b, Cm3a and Cm3b.

Furthermore, in this embodiment, sampling capacitors Ci1 and Ci2 are included to illustrate an example of a differential structure of the auto-zeroing circuitry.

Input chopper 20 may comprise first switches 21a, 21b for realizing first mode operation, and second switches 22a, 22b for realizing second mode operation. Input switch S1 described above with reference to FIGS. 5A and 6A is replaced with third switches 23a, 23b. Further input switch may be realized using third switches 23a, 23b or may be realized using separate switches (not shown).

Output chopper 30 may comprise fourth switches 31a, 31b for realizing first mode operation, and fifth switches 32a, 32b for realizing second mode operation. Output switch S3 and further output switch S4 described above with reference to FIG. 6A are replaced with sixth switches 33a, 33b and seventh switches 34a, 34b, respectively.

Control unit 40 may control first switches 21a, 21b and second switches 22a, 22b to control the operating mode of input chopper 20, third switches 23a, 23b and fourth switches 31a, 31b to control the operating mode of output chopper 30, and fifth switches 32a, 32b, sixth switches 33a, 33b and seventh switches 34a, 34b to control the operating mode of auto-zeroing amplifier 10.

FIG. 8 illustrates a circuit 50 according to an embodiment of the present disclosure, having a circuit input 2a and a circuit output 2b. Circuit 50 comprises auto-zeroing amplifier 10, which may be identical or similar to auto-zeroing amplifier 10 described above with reference to FIG. 2-7, or circuit 100b described with reference to FIG. 1B. Circuit 50 also comprises a first capacitive unit C1 (e.g., one or more first capacitors) and a second capacitive unit C2 (e.g., one or more second capacitors). For convenience, first capacitive unit C1 and second capacitive unit C2 are illustrated as a single capacitor in FIG. 8. Such a configuration with first capacitive unit C1 and second capacitive unit C2 may be referred to as a capacitively coupled (instrumentation) amplifier. Circuit 1 may be comprised entirely in circuit 50.

Circuit 50 additionally comprises a biasing unit 51 configured to apply a biasing voltage to first capacitive unit C1 and optionally also to second capacitive unit C2. In particular, biasing unit 51 may apply the biasing voltage during auto-zeroing phase operation of auto-zeroing amplifier 10, and not during output phase operation. Instead, during output phase operation of auto-zeroing amplifier, first capacitive unit C1 and, if applicable, second capacitive unit C2 may be configured to substantially maintain the charge stored thereon by having applied the biasing voltage during auto-zeroing phase operation. In this manner, circuit 50 and in particular the input of auto-zeroing amplifier 10 (e.g., the input of amplifier 11) may be biased at a correct DC voltage.

Biasing unit 51 as described above eliminates the need for a relatively large biasing resistor to be connected between the input of the amplifier and a reference supply voltage, which would otherwise contribute to noise as well as to the size of the circuit. Moreover, biasing of first capacitive unit C1 can conveniently be performed during auto-zeroing phase operation where the signal path from circuit input 2a to circuit output 2b is temporarily interrupted. Biasing unit 51 may allow forming a virtual ground at the input of amplifier 11 for AC signals by appropriately biasing first capacitive unit C1.

For example, biasing unit 51 may be configured to apply, using a first switching unit (not shown in FIG. 8), a first biasing voltage to a first terminal of first capacitive unit C1 connected to auto-zeroing amplifier 10, during auto-zeroing phase operation. The first biasing voltage may be a reference voltage, such as ground. The first terminal of first capacitive unit C1 may also be electrically connected to a first terminal of second capacitive unit C2, such that biasing unit 51 can simultaneously bias both first capacitive unit C1 and second capacitive unit C2.

Biasing unit 51 may also be configured to apply, during auto-zeroing phase operation, a second biasing voltage to a second terminal of first capacitive unit C1 connected directly or indirectly to circuit input 2a. The second biasing voltage may be another reference voltage. In some embodiments, the second biasing voltage may be a common-mode voltage of an input signal presented at circuit input 2a. If circuit input 2a is directly connected to the second terminal of first capacitive unit C1, biasing unit 51 may not need to apply the second biasing voltage. If circuit input 2a is instead indirectly connected to the second terminal of first capacitive unit C1, biasing unit 51 may for example apply, using a second switching unit (not shown in FIG. 8), the common-mode voltage of the input signal at the circuit input 2a to the second terminal of first capacitive unit C1.

Biasing unit 51 may also be configured to apply, during auto-zeroing phase operation, a third biasing voltage to a second terminal of second capacitive unit C2 connected directly or indirectly to circuit output 2b. The third biasing voltage may be another reference voltage. In some embodiments, the third biasing voltage may be a common-mode voltage at circuit output 2b. If circuit output 2b is directly connected to the second terminal of second capacitive unit C2, biasing unit 51 may not need to apply the third biasing voltage. If circuit output 2b is instead indirectly connected to the second terminal of second capacitive unit C2, biasing unit 51 may for example apply, using a third switching unit (not shown in FIG. 8), the common-mode voltage of the input signal at the circuit output 2b to the second terminal of second capacitive unit C2.

Optionally, circuit 50 further comprises input chopper 20, output chopper 30, and a feedback chopper 52, which may be identical or similar to input chopper 20 and/or output chopper 30 described above with reference to FIG. 2-7. An advantage of this configuration is that, aside from mitigating offset, an operating range of circuit 50 may be extended down to DC signals, since input chopper 20 can effectively modulate input signals at circuit input 2a to a frequency suitable for passing through first capacitive unit C1 and second capacitive unit C2.

Circuit 50 may further comprise a control unit 60 for controlling auto-zeroing amplifier 10, biasing unit 51 and, if applicable, input copper 20, output chopper 30, and feedback chopper 52. For convenience, interconnections between control unit 60 and other elements in FIG. 8 are not shown. Here, it is noted that control unit 60 may be identical or similar in function as control unit 40 described above with reference to FIG. 2-7. That is, it may control auto-zeroing amplifier 10, input chopper 20 and output chopper 30 in an identical or similar manner, and may additionally control feedback chopper 52 synchronously to input chopper 20 and output chopper 30. However, it need not be the case that control unit 60 employs the same control scheme as control unit 40 described above with reference to FIG. 2-7. For example, control unit 60 may instead control auto-zeroing amplifier 10, input copper 20 and output chopper 30 without taking into account whether the sampled offset signal is averaged out at circuit output 2b.

Control unit 60 may control auto-zeroing amplifier 10 to periodically operate in the auto-zeroing phase and subsequently in the output phase, and may control biasing unit 51 accordingly during the auto-zeroing phase operation of auto-zeroing amplifier 10.

Similarly to FIG. 6A and FIG. 7, auto-zeroing amplifier may be further operable in a dummy auto-zeroing mode, and control unit 60 may control auto-zeroing amplifier 10 to periodically operate in the auto-zeroing phase followed by the output phase, and dummy auto-zeroing phase followed by the output phase. In that case, biasing unit 51 may also apply the biasing voltage during the dummy auto-zeroing phase.

FIG. 9A illustrates a more detailed embodiment of circuit 50. Here, input chopper 20, output chopper 30 and feedback chopper 52 are implemented using switches in a similar fashion as shown for input chopper 20 and/or output chopper 30 in FIG. 7. A detailed description thereof as well as reference numbers for said switches are therefore omitted for convenience of clarity.

The first capacitive unit described with reference to FIG. 8 may include, in a differential implementation, first capacitors C1a, C1b. Similarly, the second capacitive unit described with reference to FIG. 8 may include, in a differential implementation, second capacitors C2a, C2b.

The biasing unit described with reference to FIG. 8 may include the above-described first switching unit including switches Sb1a, Sb1b, the second switching unit including switches Sb2a, Sb2b, and/or the third switching unit including switches Sb3a, Sb3b. In this embodiment, the first switching unit Sb1a, Sb1b electrically connects the first terminal of first capacitors C1a, C1b to a reference voltage, or ground in this case.

The second switching unit Sb2a, Sb2b electrically connects the second terminal of first capacitors C1a, C1b to one of the differential terminals of circuit input 2a. In this manner, a common-mode voltage of an input signal at circuit input 2a can be used as the second biasing voltage. Similarly, third switching unit Sb3a, Sb3b may electrically connect the second terminal of second capacitors C2a, C2b to one of the differential terminals of circuit output 2b. In this manner, a common-mode voltage at circuit output 2b can be used as the third biasing voltage.

As shown in FIG. 9A, second switching unit Sb2a, Sb2b may be integrated with input chopper 20 in a switch bank. Similarly, third switching unit Sb3a, Sb3b may be integrated with feedback chopper 52 in a switch bank. Furthermore, similarly to FIG. 7, output chopper 30 may include dummy auto-zeroing circuitry, and auto-zeroing amplifier 10 may be operable in the dummy auto-zeroing phase as described above with reference to FIGS. 6A and 7. For convenience of explanation, reference numbers for the dummy auto-zeroing circuitry are omitted from FIG. 9A.

Auxiliary amplifier 3 in this embodiment is connected in parallel to auto-zeroing amplifier 10 and output chopper 30. To ensure that the output of auxiliary amplifier 3 and the output of auto-zeroing amplifier 10 have a corresponding polarity, an auxiliary chopper 53 is coupled between the input of auto-zeroing amplifier 10 and the input of auxiliary amplifier 3. Auxiliary chopper 53 may be identical or similar to input chopper 20, output chopper 30 and feedback chopper 52.

Circuit 50 may further comprise an output stage amplifier 54 including Miller compensation capacitors Cm4a, Cm4b. Output stage amplifier 54 may be coupled between output chopper 30 and circuit output 2b.

Furthermore, in this embodiment, a differential implementation of the auto-zeroing circuitry is shown, including two sampling capacitors Ci1, Ci2, and amplifier 11 with a differential input and a differential output. However, the present disclosure also envisages single-ended implementation of parts or all of circuit 50.

FIG. 8B illustrates circuit 50 according to another embodiment of the present disclosure. The embodiment of FIG. 8B differs that of FIG. 8A in that first capacitors C1a, C1b can be used simultaneously for capacitively coupling input chopper 20 to amplifier 11 as well as for storing the offset signal during the auto-zeroing phase and providing offset compensation during the output phase. In particular, the biasing unit may comprise a feedback switching unit including feedback switches Sf1, Sf2. During the auto-zeroing phase, feedback switches Sf1, Sf2 may enter a closed (i.e., conductive) state to thereby form a feedback loop around amplifier 11 and provide the offset signal as at least part of the first biasing signal to first capacitors C1a, C1b. First capacitors C1a, C1b can store charge corresponding to said offset signal during the auto-zeroing phase, and can substantially maintain this charge during the subsequent output phase. In doing so, first capacitors C1a, C1b can provide offset compensation during the output phase via the capacitive coupling. This eliminates the need for additional components in circuit 50 for sampling and for generating the sampled offset signal for the purpose of compensating the offset.

In the above, various type of exemplary amplifiers are described, including transconductors and voltage amplifiers. However, the present disclosure is not limited thereto, and may equally relate to modified implementations with voltage-to-voltage amplifiers, voltage-to-current amplifiers, current-to-voltage amplifiers, and current-to-current amplifiers, and combinations thereof.

Circuit 1 and/or circuit 50 described above may be amplifier circuits and may be at least partially realized as integrated circuits on one or more semiconductor dies. Alternatively, at least part or possibly all of circuit 1 and/or circuit 50 can be implemented using discrete components. Various components may be realized using complementary metal-oxide-semiconductor (CMOS) technology or similar semiconductor technologies known in the art. Circuit 1 and/or circuit 50 may be packaged in a single semiconductor device package, as will be appreciated by the person skilled in the art.

In the abovementioned description, the present disclosure was explained using detailed embodiments thereof. However, the present disclosure is not limited to any of these embodiments in particular. Various modifications are possible without deviating from the scope of the present disclosure as defined by the appended claims and their equivalents.

1. A circuit having a circuit input and a circuit output, the circuit comprising:
an auto-zeroing amplifier comprising an amplifier and auto-zeroing circuitry, and being operable in:
an auto-zeroing phase in which the auto-zeroing circuitry is configured to sample an offset signal of the amplifier, the offset signal being indicative of an offset of the amplifier; and
an output phase in which the auto-zeroing amplifier is configured to provide an auto-zeroed output signal corresponding to an output signal of the amplifier combined with said sampled offset signal;
an input chopper electrically connected between the circuit input and an input of the auto-zeroing amplifier;
an output chopper electrically connected between the output of the auto-zeroing amplifier and the circuit output; and
a control unit configured to control the auto-zeroing amplifier, the input chopper and the output chopper such that, over a time period from the auto-zeroing amplifier entering output phase operation to again entering the output phase operation following the auto-zeroing phase operation, the sampled offset signal in the auto-zeroed output signal is substantially averaged out at the circuit output.

2. The circuit according to claim 1, wherein the input chopper and the output chopper are each configured to be operable in a first mode, in which said choppers are configured to multiply an input signal thereof by +1 or to directly couple an input thereof to an output thereof, and a second mode, in which said choppers are configured to multiply an input signal thereof by −1 or to cross-couple the input thereof to the output thereof,
wherein the control unit is configured to control the input chopper and the output chopper such that, in said time period, the sum of each first time interval, during which the input chopper and output chopper operate in the first mode, and each second time interval, during which the input chopper and output chopper transition from the first mode to the second mode, is substantially equal to the sum of each third time interval, during which the input chopper and output chopper operate in the second mode, and each fourth time interval, during which the input chopper and output chopper transition from the second mode to the first mode.

3. The circuit according to claim 2, wherein the input chopper and the output chopper are each further operable in an open mode in which said choppers are configured to disconnect the input thereof from the output thereof,
wherein the control unit is configured to control the input chopper and the output chopper to operate in the open mode during at least one of the second time intervals and/or at least one of the fourth time intervals,
wherein, preferably, transitioning from the first mode to the second mode and/or transitioning from the second mode to the first mode corresponds to operating in the open mode.

4. The circuit according to claim 3, wherein the control unit is configured to control the input chopper and the output chopper to operate in the open mode while the auto-zeroing amplifier is controlled to operate in the auto-zeroing phase, or
wherein at least one but preferably all of the second time interval(s) and fourth time interval(s) are substantially equal to a duration of auto-zeroing phase operation of the auto-zeroing amplifier.

5. (canceled)

6. The circuit according to any of the claim 2, wherein the control unit is configured to provide an auto-zeroing control signal to the auto-zeroing amplifier for controlling the auto-zeroing amplifier, and to provide a chopper control signal to the input chopper and the output chopper for controlling said input chopper and output chopper,
wherein a fundamental period of the auto-zeroing control signal is n times a fundamental period of the chopper control signal, wherein n is a multiple of 0.5.

7. (canceled)

8. The circuit according to any of the claim 2, wherein at least one of the following applies:
each first time interval is substantially identical to a respective third time interval;
each second time interval is substantially identical to a respective fourth time interval;
each first time interval is substantially identical, and/or each second time interval is substantially identical, and/or each third time interval is substantially identical, and/or each fourth time interval is substantially identical;
the first time interval(s) is/are longer than the third time interval(s), and the fourth time interval(s) is/are longer than the second time interval(s); or
the third time interval(s) is/are longer than the first time interval(s), and the second time interval(s) is/are longer than the fourth time interval(s).

9. (canceled)

10. The circuit according to any of the claim 2, wherein the input chopper and output chopper are differential components, each comprising first switches for enabling first mode operation, and a second switches for enabling second mode operation.

11. The circuit according to claim 1, wherein the amplifier is configured to amplify a signal received at an input of the amplifier and to provide the amplified signal at an output of the amplifier,
wherein, during the auto-zeroing phase, the auto-zeroing circuitry is configured to short the input of the amplifier and sample the offset signal at the output of the amplifier, and
wherein, during the output phase, the auto-zeroing amplifier is configured to provide the auto-zeroed output signal by combining the amplified signal and the sampled offset signal,
wherein the auto-zeroing circuitry comprises:
a sample-and-hold unit for sampling the offset signal;
one or more input switches for shorting the input of the amplifier during the auto-zeroing phase; and
one or more output switches for electrically connecting the output of the amplifier to the sample-and-hold unit during the auto-zeroing phase.

12. (canceled)

13. The circuit according to claim 1, wherein the auto-zeroing amplifier is further operable in a dummy auto-zeroing phase during which the auto-zeroing circuitry or dummy auto-zeroing circuitry is configured to short both the input of the amplifier and the output of the amplifier,
wherein the control unit is configured to control the auto-zeroing amplifier to alternatingly operate in the auto-zero phase followed by the output phase, and dummy auto-zero phase followed by the output phase,
wherein the control unit is configured to control the auto-zeroing amplifier such that a duration of the auto-zeroing phase is substantially equal to a duration of the dummy auto-zeroing phase.

14. (canceled)

15. The circuit according to claim 13, wherein the one or more input switches are configured to short the input of the amplifier while the auto-zeroing amplifier is operating in the dummy auto-zeroing mode, or wherein the dummy auto-zeroing circuitry comprises one or more further input switches configured to short the input of the amplifier while the auto-zeroing amplifier is operating in the dummy auto-zeroing mode,
wherein the auto-zeroing circuitry or the dummy auto-zero circuitry comprises one or more further output switches configured to short the output of the amplifier while the auto-zeroing amplifier is operating in the dummy auto-zeroing mode.

16. (canceled)

17. The circuit according to claim 3, wherein the auto-zeroing amplifier is further operable in a dummy auto-zeroing phase during which the auto-zeroing circuitry or dummy auto-zeroing circuitry is configured to short both the input of the amplifier and the output of the amplifier,
wherein the control unit is configured to control the auto-zeroing amplifier to alternatingly operate in the auto-zero phase followed by the output phase, and dummy auto-zero phase followed by the output phase,
wherein the control unit is configured to control the input chopper and the output chopper to operate in the open mode while the auto-zeroing amplifier is operating in the dummy auto-zeroing phase.

18. The circuit according to claim 1, further comprising one or more further amplifying stages electrically connected between the output chopper and the circuit output,
wherein the one or more further amplifying stages comprises an integrator, such as a Miller-compensated amplifier stage.

19. (canceled)

20. The circuit according to claim 1, wherein the auto-zeroing amplifier is configured for amplifying low-frequency signals, the circuit further comprising an auxiliary amplifier electrically connected in parallel to the input chopper, the auto-zeroing amplifier and the output chopper, the auxiliary amplifier being configured for amplifying high-frequency signals.

21. The circuit according to claim 1, wherein a ratio of a duration of the auto-zeroing phase and a total duration of the time period is less than 0.1, preferably less than 0.05, more preferably less than 0.02.

22. The circuit according to claim 1, further comprising:
a first capacitive unit electrically connected between the input chopper and the input of the amplifier;
a feedback chopper electrically connected between the circuit output and the input of the amplifier;
a second capacitive unit electrically connected between the feedback chopper and the input of the amplifier; and
a biasing unit configured to, only during auto-zeroing phase operation among auto-zeroing phase operation and output phase operation, apply a biasing voltage across the first capacitive unit,
wherein the control unit is configured to control the feedback chopper synchronously with the input chopper and the output chopper.

23. The circuit according to claim 22, wherein the biasing unit comprises a first switching unit configured to apply a first biasing voltage to a first terminal of the first capacitive unit electrically connected to the input of the amplifier,
wherein the first biasing voltage is a reference voltage, and/or
wherein the one or more input switches are formed by the first switching unit.

24. (canceled)

25. (canceled)

26. The circuit according to claim 22, wherein the biasing unit comprises a feedback switching unit configured to apply the offset signal as at least part of a first biasing voltage to a first terminal of the first capacitive unit electrically connected to the input of the amplifier,
wherein the first capacitive unit is configured to store charge corresponding to the offset signal during auto-zeroing phase operation of the auto-zeroing amplifier and to substantially maintain said charge during output phase operation to thereby compensate the offset of the amplifier during output phase operation,
wherein the feedback switching unit and the first capacitive unit together form the auto-zeroing circuitry,
wherein, to apply the offset signal as at least part of the first biasing voltage, the feedback switching unit is configured to form a feedback loop for the amplifier during auto-zeroing phase operation.

27. (canceled)

28. The circuit according to any of the claim 22, wherein the biasing unit comprises a second switching unit configured to apply, during the auto-zeroing phase, a second biasing voltage to a second terminal of the first capacitive unit electrically connected to the input chopper,
wherein the second biasing voltage is a reference voltage or a common-mode voltage of an input signal received at the circuit input.

29. (canceled)

30. The circuit according to any of the claim 22, wherein the biasing unit comprises a third switching unit configured to apply, during the auto-zeroing phase, a third biasing voltage to a second terminal of the second capacitive unit electrically connected to the feedback chopper,
wherein the third biasing voltage is a reference voltage or a common-mode voltage at the circuit output.

31. (canceled)

32. A method for operating a circuit having a circuit input and a circuit output, wherein the circuit comprises:
an auto-zeroing amplifier comprising an amplifier and auto-zeroing circuitry, and being operable in an auto-zeroing phase in which the auto-zeroing circuitry is configured to sample an offset signal of the amplifier, the offset signal being indicative of an offset of the amplifier, and an output phase in which the auto-zeroing amplifier is configured to provide an auto-zeroed output signal corresponding to an output signal of the amplifier combined with said sampled offset signal;
an input chopper electrically connected between the circuit input and an input of the auto-zeroing amplifier; and
an output chopper electrically connected between the output of the auto-zeroing amplifier and the circuit output,
wherein the method comprises controlling the auto-zeroing amplifier, the input chopper and the output chopper such that, in a time period from entering output phase operation to again entering the output phase operation following the auto-zero phase operation, the sampled offset signal in the auto-zeroed output signal is substantially averaged out at the circuit output.
